(19) United States
(12) Patent Application Publication
(10) Pub. No.: US 2026/0036899 A1
(43) Pub. Date: Feb. 5, 2026

(54) DIFFERENTIABLE EDGE-BASED OPTICAL PROXIMITY CORRECTION

(71) Applicant: NVIDIA Corp., Santa Clara, CA (US)

(72) Inventors: Guojin Chen, Santa Clara, CA (US); Haoyu Yang, Round Rock, TX (US); Haoxing Ren, Austin, TX (US)

(73) Assignee: NVIDIA Corp., Santa Clara, CA (US)

(21) Appl. No.: 19/178,263

(22) Filed: Apr. 14, 2025

Related U.S. Application Data
(60) Provisional application No. 63/679,269, filed on Aug. 5, 2024.

(51) Int. Cl. G03F 1/36; G06T 7/11; G06T 7/13; G06T 7/73; G06T 15/06

(52) U.S. Cl. CPC G03F 1/36; G06T 7/11; G06T 7/13; G06T 7/75; G06T 15/06; G06T 2207/30148; G06T 2207/30242

(57) ABSTRACT

Lithography mask generation processes utilizing a forward process that decomposes a resist pattern into segments and rasterizes the segments into a mask pattern using ray casting, and a backward process that determines lithography gradients for edge movements that incorporate mask rule constraints and propagates the lithography gradients into gradients and velocities for the segments.

### CROSS-REFERENCE TO RELATED APPLICATIONS

This application claims priority and benefit under 35 U.S.C. 119 (e) to U.S. Application Ser. No. 63/679,269, “Differentiable Edge-Based OPC”, filed on Aug. 5, 2024, the contents of which are incorporated herein by reference in their entirety.

### BACKGROUND

Optical proximity correction (OPC) is utilized in semiconductor manufacturing to enable the continued scaling down in the size and density of integrated circuits. Pixel-based OPC, termed as inverse lithography technology (ILT), has gained interest due to its flexibility and precision. However its complexity and intricate features may lead to challenges in masking, increased defects, and higher costs.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 depicts an exemplary differentiable edge-based optical proximity correction (OPC) process.

FIG. 2 depicts logic to segment target polygon edges into smaller segments of a pre-defined length.

FIG. 3A and FIG. 3B depict Straight-Through-Estimator (STE) forward and backward passes, respectively.

FIG. 4 depicts logic to identify intersections and adjust corner parameters in accordance with one embodiment.

FIG. 5 depicts logic to parallelize ray casting for edge to mask rasterization in accordance with one embodiment.

FIG. 6 depicts logic to transform masks to edge gradients, with velocity, in accordance with one embodiment.

FIG. 7A and FIG. 7B depict examples of SRAF seeding and final SRAF placement in a mask, respectively.

FIG. 8 depicts a parallel processing unit in accordance with one embodiment.

FIG. 9 depicts a general processing cluster in accordance with one embodiment.

FIG. 10 depicts a memory partition unit in accordance with one embodiment.

FIG. 11 depicts a streaming multiprocessor in accordance with one embodiment.

FIG. 12 depicts a processing system in accordance with one embodiment.

FIG. 13 depicts an exemplary processing system in accordance with another embodiment.

FIG. 14 depicts a graphics processing pipeline in accordance with one embodiment.

### DETAILED DESCRIPTION

Disclosed herein are differentiable OPC mechanisms obtaining benefits of both edge-based OPC and pixel-based OPC (also known as Inverse Lithography) in generation of physical lithography masks. By employing a mask rule-aware gradient-based optimization approach, the disclosed mechanisms efficiently guide mask edge segment movement during mask optimization, minimizing wafer error by propagating true gradients from a cost function back to the mask edges.

The disclosed mechanisms may achieve lower edge placement error in physical lithography masks while reducing manufacturing cost compared to conventional OPC mechanisms, bridging the gap between the high accuracy of pixel-based OPC and the practicality required for industrial adoption.

In a forward process, the disclosed mechanisms apply a flexible segmentation approach and ray casting (that may be accelerated on graphics processing units, e.g., utilizing CUDA instructions). This expedites differentiable layout rasterization. The disclosed mechanisms further apply a novel mechanisms to optimize sub-resolution assist features seed generation placement.

In a backward pass, the disclosed mechanisms determine lithography gradients for edge movements using a chain-rule approach and that incorporate mask rule constraints to ensure manufacturability. By combining these improvements, the disclosed mechanisms achieve improved OPC performance with high manufacturability.

The disclosed mechanisms incorporate differentiable edge-based OPC with integrated edge placement error loss, and utilize mask rule check gradients for mask optimization. The disclosed mechanisms further provide a flexible segmentation approach and a CUDA-accelerated ray casting mechanism to expedite layout rasterization. Edge segment gradients are efficiently determined using a chain-rule mechanism to ensure manufacturability. A novel SRAF seed generation algorithm is applied, leveraging gradients for optimal SRAF placement and further optimization.

The disclosed mechanisms may apply a sum of coherent systems (SOCS) decomposition of a 193 nm wavelength system as the optical model for lithography modeling. A sum of coherent systems decomposition is a technique for modeling complex systems by decomposing them into a sum of contributions from simpler, coherent subsystems. Coherent systems are those where the system structure function is monotonic, meaning that each component provides a consistent contribution to the overall system function.

The intensity of the aerial image I generated by a mask may be modeled as a sum of coherent systems by convolving the mask M with a set of optical kernels hᵢ∈H, resulting in an

$${N}_{k}^{th}$$

order approximation:

$$I ( x , y ) \approx {\sum }_{i = 1}^{{N}_{k}} {σ}_{i} \vert M ( x , y ) ⊗ {h}_{i} ( x , y ) {\vert}^{2} \qquad Eq . 1$$

where ⊗ denotes the convolution operation, hᵢ is the i^{th} kernel of kernel set H, and σᵢ is a weight assigned to the i^{th} coherent sub-system. M(x, y) represents the pixel value at the point (x, y) of the mask image M. A constant threshold resist model (CTR) may be applied to convert the aerial image intensity I to the printed resist image Z:

$$Z ( x , y ) = \{ \begin{matrix}1 , & if I ( x , y ) > {I}_{th} \\ 0 , & otherwise\end{matrix} \qquad Eq . 2$$

where Iₜₕ is a configured intensity threshold below which no resist is presented on the wafer.

The disclosed mechanisms may apply squared L₂ error, process variation band, and edge placement error as metrics of performance evaluation (mask quality). A mask fracturing shot count may also be applied to evaluate mask complexity and manufacturability.

Squared L₂ error (Mean Square Error, i.e., MSE) may be applied to measure a difference between the nominal resist image Zₙₒₘ (e.g., resulting from optical simulation of the mask into a resist pattern) and the target (ideal) resist image T, according to

$${L}_{2} ( {Z}_{nom} , T ) = {\vert {Z}_{n o m} - T \vert}_{2}^{2} \qquad Eq . 3$$

Process variation band evaluates the robustness of the mask against different process conditions. Process variation band may be determined by measuring a bitwise XOR region between the printed images from the maximum Zₘₐₓ and minimum Zₘᵢₙ process conditions (e.g., ±2%). A smaller process variation band indicates a more robust mask. The process variation band may be determined according to

$$P V B ( {Z}_{max} , {Z}_{min} ) = {\vert {Z}_{max} - {Z}_{min} \vert}_{2}^{2} \qquad Eq . 4$$

Edge placement error quantifies the geometric distortion of the resist image. Edge placement error may be calculated by sampling points along edges of target shapes and counting a number of points where a distance between the target and a printed pattern exceeds a predefined threshold.

Shot count (#Shot) is a number of decomposed rectangles that replicate the original mask to within the desired precision.

Given a target mask design T, the disclosed mechanisms determine a set of boundary segments S={s₁, s₂, . . . , sᵢ}, and a binary mask M∈{0, 1}^{m×n} formed by the matrix inside the boundary composed of these segments S, where m and n are the dimensions of T. An objective is configured to determine a corresponding printed mask image Z that minimizes the weighted sum of EPE, L₂, PVB, and #shots.

Applying differentiable edge-based optical proximity correction to arbitrary circuit layout patterns, while utilizing minimal additional parameters such as edge placement error values, encounters several challenges. A first challenge is to enable the flexible movement of segments in Manhattan geometries modeling the mask pattern, particularly at corners. A second challenge involves mapping discrete edge movements to a continuous space to enable efficient mask update iterations. A third challenge involves maintaining compatibility with the chain rule for differentiation during the rasterization process that converts edge parameters into pixel binary masks.

The disclosed mechanisms apply movement and update mechanisms for edge segments in mask patterns, and ray casting mechanisms for rasterization (e.g., CUDA-accelerated). The disclosed mechanisms may apply lithography gradients to iteratively update the movement of edge segments until a final mask is achieved.

The disclosed mechanisms may further apply improved mechanisms for placement of sub-resolution assist features in the mask. Sub-resolution assist features (SRAFs) are utilized in lithography to enhance the resolution and fidelity of the printed features on a photomask. SRAFs are small, non-printing features added to the mask layout around the main features. They function to improve the process window and image contrast during photolithographic patterning, thus enabling finer and more accurate features to be transferred onto a (e.g., silicon) wafer. SRAFs thereby assist in reducing variations due to optical effects and enhance the overall manufacturability of integrated circuits.

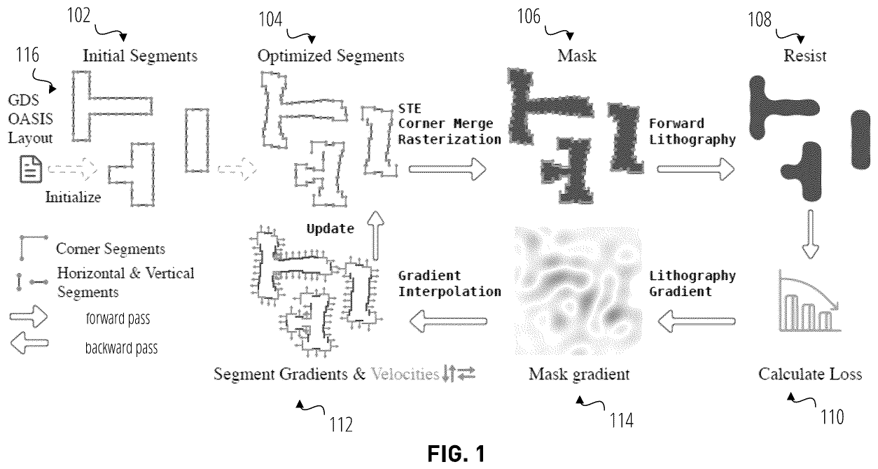

FIG. 1 depicts a process for generating a circuit mask in one embodiment. An initial resist segment set 102 is generated for a circuit layout 116 as a collection Manhattan shapes. Manhattan shapes, also known as orthogonal shapes or rectilinear polygons, are geometric figures where all edges are aligned with the Cartesian axes, meaning that (in two dimensions) they consist entirely of horizontal and vertical line segments.

The initial resist segment set 102 undergoes an optimization process that is described more fully below. A mask image 106 is produced from the optimized resist segment set 104 via application of straight-through-estimation (STE), corner merging, and rasterization.

Forward lithography simulation is applied to convert the mask image 106 into a resist image 108 (the resist pattern on a wafer, corresponding to the mask image 106. A loss determination 110 is performed between the derived resist image 108 and the ideal resist image to manufacture the circuit. This produces a lithography gradient that is utilized to derive a mask gradient 114, which is interpolated to generate segment gradients and velocities 112 that are applied to update the optimized resist segment set 104 for a next iteration.

The backward pass requires transforming the gradients from the lithography model, which comprise the shape [W, H], into gradients for the mask segments, represented as a tensor of shape [Ns, 2, 2]. To accomplish this, the disclosed mechanisms may first derive the gradient of the mask tensor with respect to the edge parameters via differentiation.

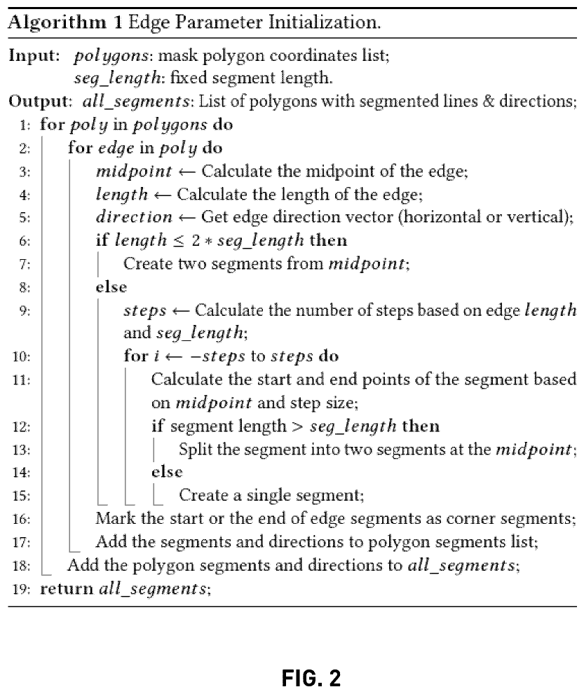

FIG. 2 depicts logic to segment target polygon edges into smaller segments of a pre-defined length. The logic determines a minimal set of segments, denoted as S∈R^{Ns×2×2}, where R represents the real number domain and Nₛ is the number of segments. Each segment sᵢ∈S may be represented by its starting and ending coordinates in vector form: [[x1, y1], [x2, y2]]. The segment set S may be applied as parameters for optical proximity correction, providing increased flexibility in handling corner edges compared to traditional edge-based mechanisms that are limited to optimizing edge movement distance.

Each segment sᵢ of the set S may be associated with a direction vector dᵢ∈D. Assigning direction vectors to the segments may improve reconstruction of the segments back into polygons by defining their direction of movement.

The depicted logic may help ensure compliance with mask rule constraints by merging excessively short segments (segments shorter than a configured minimum length) into longer ones as needed.

After determining the segments S and their corresponding directions D, the disclosed mechanisms establish a velocity vector vᵢ∈V for each segment sᵢ. The velocity vector correlates the movement of edge segments with the gradients obtained from lithography simulations.

In conventional set-based ILT (LSILT), a velocity component is determined as the projection of the gradient of the implicit level-set function ϕ onto the mask plane, denoted as ∇ϕ, and may be a vector in any direction. However, in the disclosed mechanisms, the movement direction vᵢ of an edge segment sᵢ is restricted to be perpendicular to its direction vector dᵢ, either horizontal or vertical, satisfying the condition vᵢ·dᵢ=0. Additionally, the default orientation of all velocity vectors vᵢ is set to point outward from the polygon, as depicted in FIG. 1.

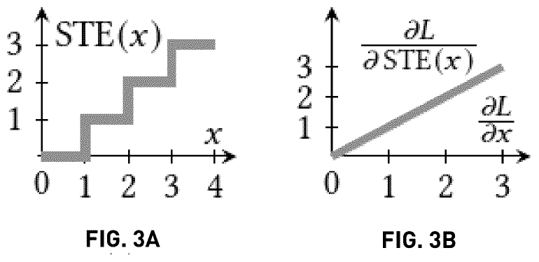

FIG. 3A and FIG. 3B depict Straight-Through-Estimator (STE) forward and backward passes, respectively.

The segment set S may be stored as learnable parameters in tensor S∈R^{Ns×2×2}, while the set of segment velocities V is a fixed (non-learnable parameter) tensor V∈R^{Ns×2}, where Nₛ is the number of segments.

The disclosed mechanisms apply a forward pass of learnable parameters S to the resist image Z over five differentiable steps: edge parameter rounding, merging corner edges, edge-to-mask rasterization, forward lithography simulation, and loss calculation.

The edge parameters S are real-valued, whereas the edge coordinate system is integer valued. This difference results in the rounding operation becoming non-differentiable. To address this issue and enable a differentiable process, the disclosed mechanisms apply a straight-through estimator (STE) for rounding the edge parameters S.

$${\overline{x}}_{i} = S T E ( {x}_{i} ) , {\overline{y}}_{i} = S T E ( {y}_{i} ) , {\overline{s}}_{i} = STE ( {s}_{i} ) , \overline{S} = S T E ( S ) ; \qquad Eq . 5$$

$$\overline{x} = STE ( x ) = \{ \begin{matrix}round ( x ) , & forward pass STE \\ \frac{\partial L}{\partial x} , & backward pass STE\end{matrix}$$

A straight-through estimator (STE) replaces non-differentiable operations in the forward pass with an approximate or surrogate operation that is differentiable. During the backward pass, the gradients are computed through this surrogate function instead of the original operation. The STE thereby enables the gradient to be propagated through layers that would otherwise block it due to non-differentiable operations, enabling effective training of models that incorporate discrete decisions.

The forward pass illustrated in FIG. 3A applies the rounding function to S, while the backward pass directly propagates the gradients from S̅ to S, as shown in FIG. 3B.

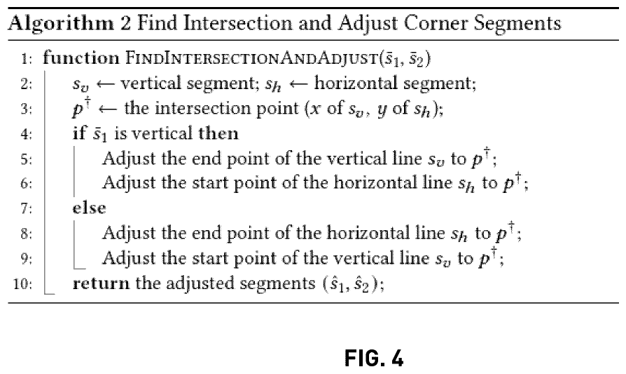

FIG. 4 depicts logic to identify intersections and adjust corner parameters in accordance with one embodiment.

During the optimization, as edges move, the endpoints of different segments separate. For non-corner segments, the segment length remains unchanged because these types of segments move only along the normal direction.

Newly formed edges between adjacent segments, resulting from the movement, may be formed between the endpoints of the neighboring edges without additional processing. However, for segments adjacent to corners, the movement directions differ, and additional processing is performed to derive these edges. After the movement, a new intersection point between such segments may lie outside the two segments. Therefore, it is necessary to additionally connect the segments adjacent to the corners.

An example of the logic to perform this processing is depicted in Algorithm 2 of FIG. 2. After the forward pass of the corner merging operation, the adjusted edge parameters Ŝ reflect the re-connection of adjacent segments at the corners.

In the backward pass, the gradients are directly propagated to the rounded edge parameters S̅.

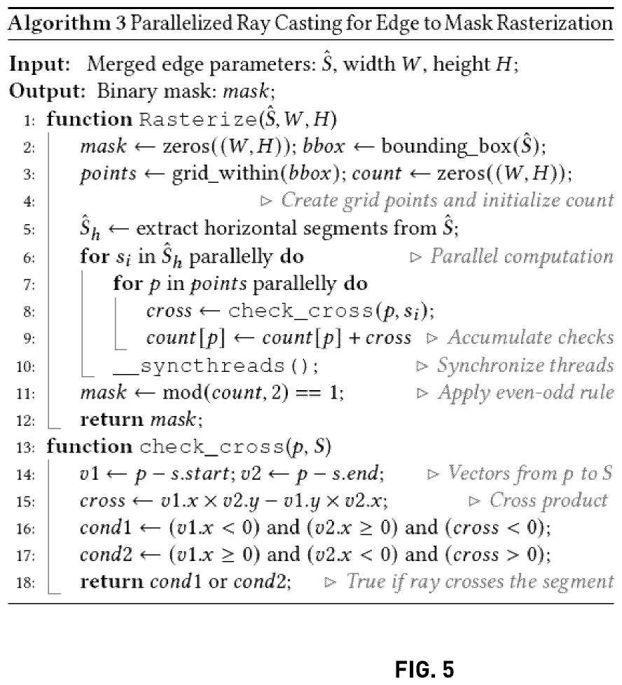

FIG. 5 depicts logic to parallelize ray casting for edge-to-mask rasterization in accordance with one embodiment. This edge-to-pixel rasterization presents a challenge, as the lithography model characterized by Eq. 1 accepts only a pixel-based mask input M. The rasterization process must be differentiable to enable the gradient flow to reach the edge parameters from the mask, and this step must execute with high efficiency because it is performed in every optimization epoch.

Traditional edge-based optical proximity correction mechanisms move segments and then fill or subtract a corresponding binary matrix at the new segment positions. This approach may not execute efficiently due to the requirement to sequentially access each segment and convert the segment's displacement into mask indices, repeatedly reading and modifying the corresponding locations.

The disclosed mechanisms effectively generate a binary (black-and-white) mask from rounded edge parameters using, for example, an accelerated ray casting mechanism. An example of the logic to implement this mechanism is depicted in Algorithm 3 of FIG. 5.

The logic depicted in FIG. 5 embodies an execution-efficient, fully-parallelized mechanism for generating a binary mask from edge parameters using ray casting. The main process, Rasterize, initializes an empty mask and a count matrix, then extracts horizontal segments from the edge parameters. Because the polygons in the mask are Manhattan rectangles and closed shapes, the mechanism only processes segments along one direction (either horizontal or vertical), reducing the computational cost by half.

For each segment, the mechanism executes parallel computation across all grid points within the bounding box via the check_cross process, to determine ray-segment intersections. The check_cross process applies cross products to efficiently check if a ray from a point intersects a segment.

After processing all segments, an even-odd rule is applied to finalize the binary mask based on a parity of intersections at each point. The logic depicted in FIG. 5 applies parallel computation, efficient ray-segment intersection checks, and the properties of Manhattan rectangles to enable fast and accurate rasterized mask generation.

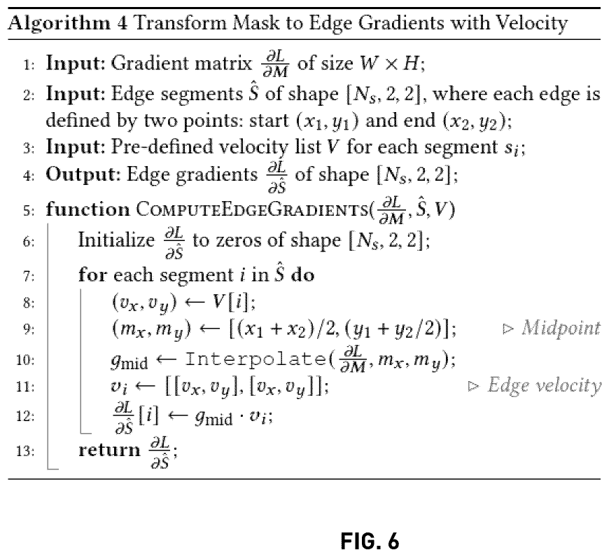

FIG. 6 depicts logic to transform masks to edge gradients with velocity, in accordance with one embodiment.

The forward pass of the rasterization process converts the edge parameters, represented as a tensor of shape [Nₛ, 2, 2], into a mask tensor of shape [W, H], where Ns is the number of segments, and W and H are the width and height of the mask, respectively.

The backward pass involves transforming the gradients from the lithography model, which are of shape [W, H], into gradients for the segments, represented as a tensor of shape [Nₛ, 2, 2]. To accomplish this, the logic first differentiates to determine the gradient of the mask tensor with respect to the edge parameters.

Let ∂L/∂M be the gradient of the loss function L with respect to the mask tensor M obtained from the lithography model. To calculate ∂L/∂Ŝ, the gradient of the loss function with as respect to the edge parameters Ŝ, the chain rule may be applied:

$$\frac{\partial L}{\partial \hat{S}} = \frac{\partial L}{\partial M} \cdot \frac{\partial M}{\partial \hat{S}} \qquad Eq . 6$$

The term ∂M/∂Ŝ represents the Jacobian matrix of the rasterization process, which maps as changes in edge parameters to changes in the mask tensor. A Jacobian matrix is a matrix of all first-order partial derivatives of a vector-valued function. The Jacobian matrix provides a linear approximation of the function near a given point. The Jacobian matrix may be computed efficiently using Algorithm 4.

The Interpolate operation at line 10 chooses the gradient at the midpoint of each segment as the representative gradient for that segment (See Eq. 12 below). Once the Jacobian matrix is obtained, the gradient of the loss function with respect to the edge parameters may be determined by multiplying the gradient of the loss function with respect to the mask tensor, ∂L/∂M, by the Jacobian matrix ∂L/∂S. This operation effectively backpropagates the gradients from the lithography model to the edge parameters, enabling the optimization of edge-based optical proximity correction using gradient-based mechanisms.

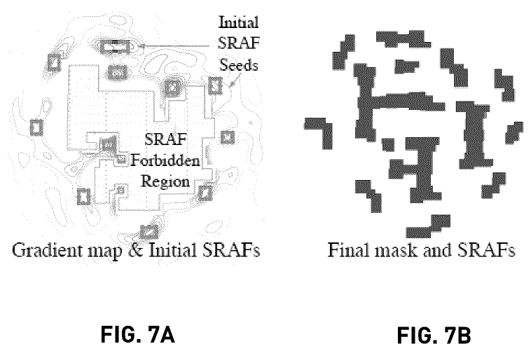

FIG. 7A and FIG. 7B depict examples of sub-resolution assist features (SRAF) seeding and final SRAF placement in a mask, respectively. SRAFs in lithography enhance sub-resolution element printability by modifying diffraction and interference effects of the resist pattern, leading to widened process windows, improved resolution, depth of focus, and reduced line edge roughness.

In conventional level set-based inverse lithography mechanisms, the implicit function ϕ is tied to the primary pattern, preventing the generation of SRAFs during optimization. Conversely, pixel-based inverse lithography mechanisms generate SRAFs during mask optimization. However, pixel-based inverse lithography is unsuited to imposing rule-based constraints on SRAFs, which may cause their growth to rely solely on gradients. This improves printability but may increase mask rule constraint violations and hotspots.

The disclosed mechanisms may mitigate these drawbacks using a two-stage SRAF optimization mechanism. The first stage involves efficient SRAF seed generation using gradient contours, and the second stage applies a differentiable edge-based optimization for the generated SRAFs. The combination of these two mechanisms may effectively obviate the problem of missing SRAFs of level set-based mechanisms, and the mask rule constraint violations of pixel-based SRAFs.

During the optimization process, regions near the main mask pattern may exhibit gradients that flip the mask value, changing it from 0 to 1. Edge-based segments do not include these regions and remain 0-valued. These gradients may therefor be enabled to contribute to SRAF generation.

Referring to FIG. 7A, the contour line of the mask gradient map depicts the position of the extreme gradient points and indicates the gradient drop rate. The position of extreme points may guide SRAF placement, while the gradient information may guide the subsequent SRAF cleanup process. The disclosed mechanisms expand the mask by a particular distance that is related to the mask rules, thereby generating an SRAF ‘forbidden region’. In FIG. 7A, gradient contour lines are depicted outside the SRAF forbidden region.

The extreme points and the corresponding contour aspect ratios are applied to set the center point of the SRAF seeds. The initial SRAF minimum width/length is set to a fixed value, and the shape and placement of the SRAF are determined based on the aspect ratio. This step does not require precise SRAF generation; it only needs to determine the initial position and aspect ratio.

In the second stage, the generated seeds depicted in FIG. 7A are processed using a segmentation mechanism (e.g., Algorithm 1) to generate new segments that added to the optimization process, whereby the SRAFs are optimized together with the mask.

To accelerate the SRAF optimization process, a multi-resolution mechanism may be utilized. SRAF seeds are generated at low resolution, and then the seeds and mask are refined in high resolution for more precise optimization. Exemplary results are depicted in FIG. 7B.

The two-stage SRAF optimization mechanism may thereby enable the generation of SRAFs that enhance printability while minimizing mask rule constraint violations.

The lithography mask generation mechanisms disclosed herein may be implemented in and/or by computing devices utilizing one or more graphic processing unit (GPU) and/or general purpose data processor (e.g., a ‘central processing unit’ or CPU). For example, some or all of the disclosed mechanisms may be implemented as instructions that configure/operate one or more data processor, stored on a non-volatile media (e.g., a machine-readable medium). Exemplary architectures will now be described that may be configured to implement the mechanisms disclosed herein.

The following description may use certain acronyms and abbreviations as follows:
“DPC” refers to a “data processing cluster”;
“GPC” refers to a “general processing cluster”;
“I/O” refers to a “input/output”;
“L1 cache” refers to “level one cache”;
“L2 cache” refers to “level two cache”;
“LSU” refers to a “load/store unit”;
“MMU” refers to a “memory management unit”;
“MPC” refers to an “M-pipe controller”;
“PPU” refers to a “parallel processing unit”;
“PROP” refers to a “pre-raster operations unit”;
“ROP” refers to a “raster operations”;
“SFU” refers to a “special function unit”;
“SM” refers to a “streaming multiprocessor”;
“Viewport SCC” refers to “viewport scale, cull, and clip”;
“WDX” refers to a “work distribution crossbar”; and
“XBar” refers to a “crossbar”.

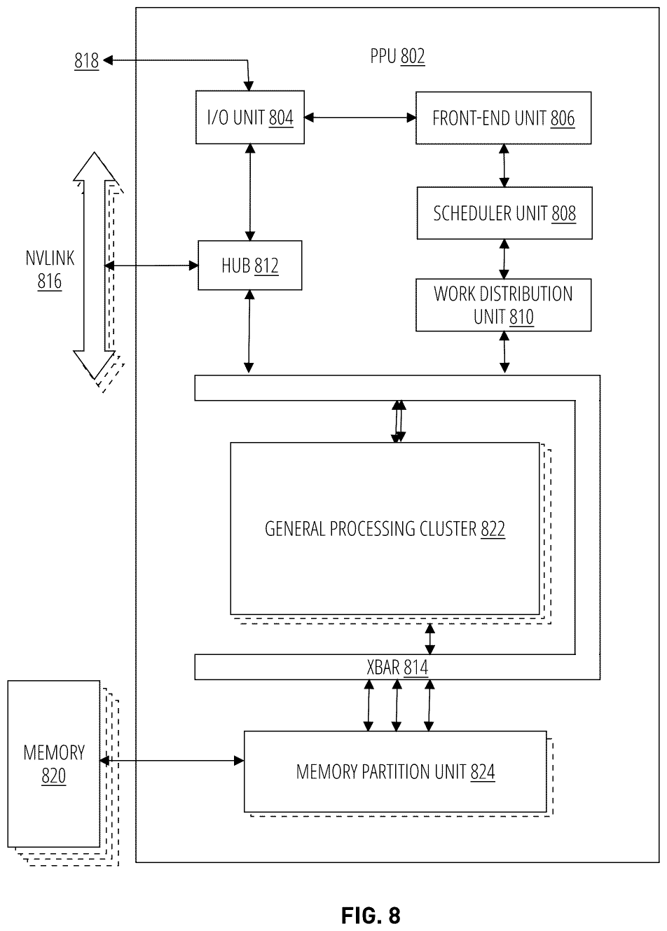

FIG. 8 depicts a parallel processing unit 802, in accordance with an embodiment. In an embodiment, the parallel processing unit 802 is a multi-threaded processor that is implemented on one or more integrated circuit devices. The parallel processing unit 802 is a latency hiding architecture designed to process many threads in parallel. A thread (e.g., a thread of execution) is an instantiation of a set of instructions configured to be executed by the parallel processing unit 802. In an embodiment, the parallel processing unit 802 is a graphics processing unit (GPU) configured to implement a graphics rendering pipeline for processing three-dimensional (3D) graphics data in order to generate two-dimensional (2D) image data for display on a display device such as a liquid crystal display (LCD) device. In other embodiments, the parallel processing unit 802 may be utilized for performing general-purpose computations. While one exemplary parallel processor is provided herein for illustrative purposes, it should be strongly noted that such processor is set forth for illustrative purposes only, and that any processor may be employed to supplement and/or substitute for the same.

One or more parallel processing unit 802 modules may be configured to accelerate thousands of High Performance Computing (HPC), data center, and machine learning applications. The parallel processing unit 802 may be configured to accelerate numerous deep learning systems and applications including autonomous vehicle platforms, deep learning, high-accuracy speech, image, and text recognition systems, intelligent video analytics, molecular simulations, drug discovery, disease diagnosis, weather forecasting, big data analytics, astronomy, molecular dynamics simulation, financial modeling, robotics, factory automation, real-time language translation, online search optimizations, and personalized user recommendations, and the like.

As shown in FIG. 8, the parallel processing unit 802 includes an I/O unit 804, a front-end unit 806, a scheduler unit 808, a work distribution unit 810, a hub 812, a crossbar 814, one or more general processing cluster 822 modules, and one or more memory partition unit 824 modules. The parallel processing unit 802 may be connected to a host processor or other parallel processing unit 802 modules via one or more high-speed NVLink 816 interconnects. The parallel processing unit 802 may be connected to a host processor or other peripheral devices via an interconnect 818. The parallel processing unit 802 may also be connected to a local memory comprising a number of memory 820 devices. In an embodiment, the local memory may comprise a number of dynamic random access memory (DRAM) devices. The DRAM devices may be configured as a high-bandwidth memory (HBM) subsystem, with multiple DRAM dies stacked within each device. The memory 820 may comprise logic to configure the parallel processing unit 802 to carry out aspects of the techniques disclosed herein.

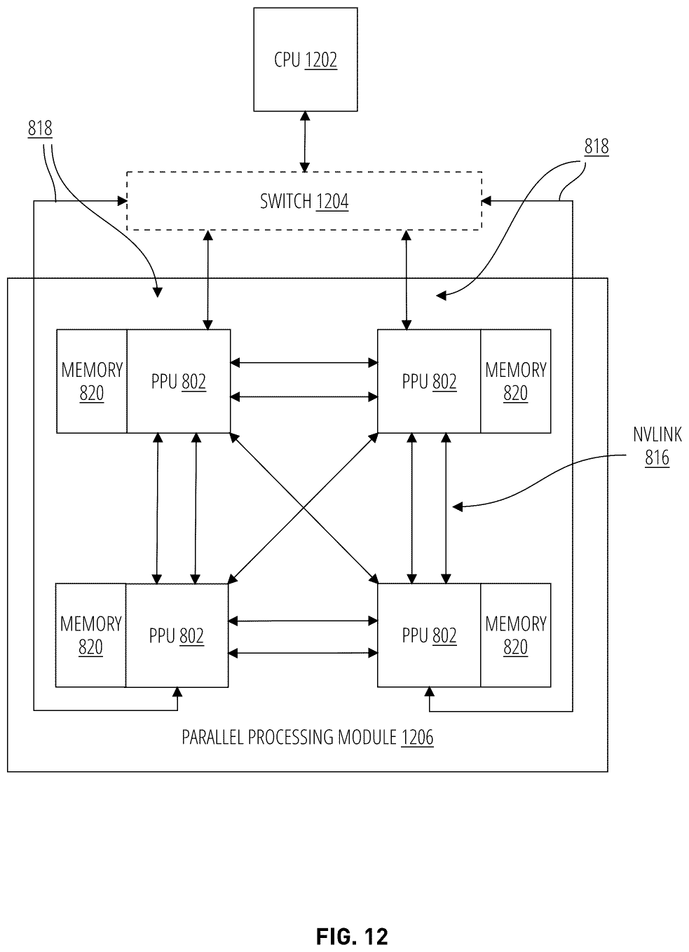

The NVLink 816 interconnect enables systems to scale and include one or more parallel processing unit 802 modules combined with one or more CPUs, supports cache coherence between the parallel processing unit 802 modules and CPUs, and CPU mastering. Data and/or commands may be transmitted by the NVLink 816 through the hub 812 to/from other units of the parallel processing unit 802 such as one or more copy engines, a video encoder, a video decoder, a power management unit, etc. (not explicitly shown). The NVLink 816 is described in more detail in conjunction with FIG. 12.

The I/O unit 804 is configured to transmit and receive communications (e.g., commands, data, etc.) from a host processor (not shown) over the interconnect 818. The I/O unit 804 may communicate with the host processor directly via the interconnect 818 or through one or more intermediate devices such as a memory bridge. In an embodiment, the I/O unit 804 may communicate with one or more other processors, such as one or more parallel processing unit 802 modules via the interconnect 818. In an embodiment, the I/O unit 804 implements a Peripheral Component Interconnect Express (PCIe) interface for communications over a PCIe bus and the interconnect 818 is a PCIe bus. In alternative embodiments, the I/O unit 804 may implement other types of well-known interfaces for communicating with external devices.

The I/O unit 804 decodes packets received via the interconnect 818. In an embodiment, the packets represent commands configured to cause the parallel processing unit 802 to perform various operations. The I/O unit 804 transmits the decoded commands to various other units of the parallel processing unit 802 as the commands may specify. For example, some commands may be transmitted to the front-end unit 806. Other commands may be transmitted to the hub 812 or other units of the parallel processing unit 802 such as one or more copy engines, a video encoder, a video decoder, a power management unit, etc. (not explicitly shown). In other words, the I/O unit 804 is configured to route communications between and among the various logical units of the parallel processing unit 802.

In an embodiment, a program executed by the host processor encodes a command stream in a buffer that provides workloads to the parallel processing unit 802 for processing. A workload may comprise several instructions and data to be processed by those instructions. The buffer is a region in a memory that is accessible (e.g., read/write) by both the host processor and the parallel processing unit 802. For example, the I/O unit 804 may be configured to access the buffer in a system memory connected to the interconnect 818 via memory requests transmitted over the interconnect 818. In an embodiment, the host processor writes the command stream to the buffer and then transmits a pointer to the start of the command stream to the parallel processing unit 802. The front-end unit 806 receives pointers to one or more command streams. The front-end unit 806 manages the one or more streams, reading commands from the streams and forwarding commands to the various units of the parallel processing unit 802.

The front-end unit 806 is coupled to a scheduler unit 808 that configures the various general processing cluster 822 modules to process tasks defined by the one or more streams. The scheduler unit 808 is configured to track state information related to the various tasks managed by the scheduler unit 808. The state may indicate which general processing cluster 822 a task is assigned to, whether the task is active or inactive, a priority level associated with the task, and so forth. The scheduler unit 808 manages the execution of a plurality of tasks on the one or more general processing cluster 822 modules.

The scheduler unit 808 is coupled to a work distribution unit 810 that is configured to dispatch tasks for execution on the general processing cluster 822 modules. The work distribution unit 810 may track a number of scheduled tasks received from the scheduler unit 808. In an embodiment, the work distribution unit 810 manages a pending task pool and an active task pool for each of the general processing cluster 822 modules. The pending task pool may comprise a number of slots (e.g., 32 slots) that contain tasks assigned to be processed by a particular general processing cluster 822. The active task pool may comprise a number of slots (e.g., 4 slots) for tasks that are actively being processed by the general processing cluster 822 modules. As a general processing cluster 822 finishes the execution of a task, that task is evicted from the active task pool for the general processing cluster 822 and one of the other tasks from the pending task pool is selected and scheduled for execution on the general processing cluster 822. If an active task has been idle on the general processing cluster 822, such as while waiting for a data dependency to be resolved, then the active task may be evicted from the general processing cluster 822 and returned to the pending task pool while another task in the pending task pool is selected and scheduled for execution on the general processing cluster 822.

The work distribution unit 810 communicates with the one or more general processing cluster 822 modules via crossbar 814. The crossbar 814 is an interconnect network that couples many of the units of the parallel processing unit 802 to other units of the parallel processing unit 802. For example, the crossbar 814 may be configured to couple the work distribution unit 810 to a particular general processing cluster 822. Although not shown explicitly, one or more other units of the parallel processing unit 802 may also be connected to the crossbar 814 via the hub 812.

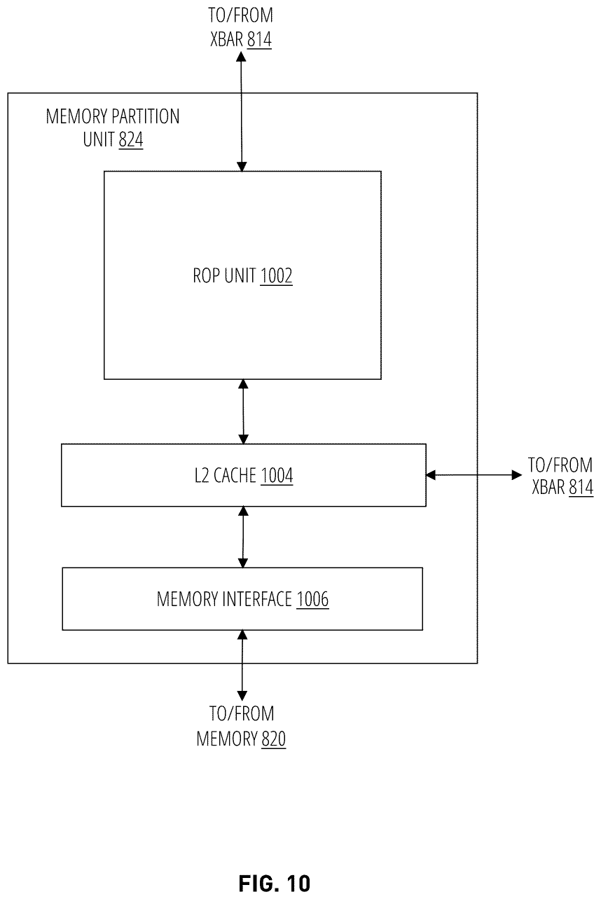

The tasks are managed by the scheduler unit 808 and dispatched to a general processing cluster 822 by the work distribution unit 810. The general processing cluster 822 is configured to process the task and generate results. The results may be consumed by other tasks within the general processing cluster 822, routed to a different general processing cluster 822 via the crossbar 814, or stored in the memory 820. The results can be written to the memory 820 via the memory partition unit 824 modules, which implement a memory interface for reading and writing data to/from the memory 820. The results can be transmitted to another parallel processing unit 802 or CPU via the NVLink 816. In an embodiment, the parallel processing unit 802 includes a number U of memory partition unit 824 modules that is equal to the number of separate and distinct memory 820 devices coupled to the parallel processing unit 802. A memory partition unit 824 will be described in more detail below in conjunction with FIG. 10.

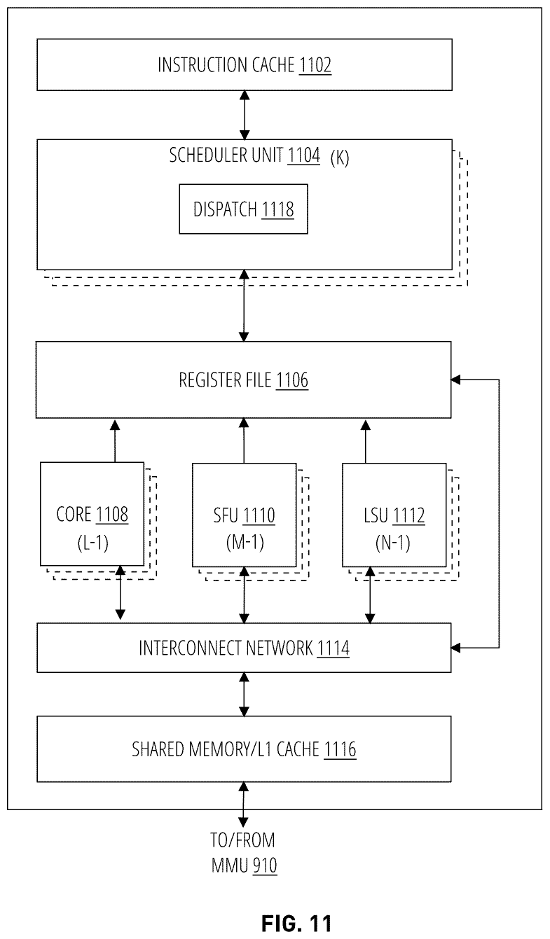

In an embodiment, a host processor executes a driver kernel that implements an application programming interface (API) that enables one or more applications executing on the host processor to schedule operations for execution on the parallel processing unit 802. In an embodiment, multiple compute applications are simultaneously executed by the parallel processing unit 802 and the parallel processing unit 802 provides isolation, quality of service (QoS), and independent address spaces for the multiple compute applications. An application may generate instructions (e.g., API calls) that cause the driver kernel to generate one or more tasks for execution by the parallel processing unit 802. The driver kernel outputs tasks to one or more streams being processed by the parallel processing unit 802. Each task may comprise one or more groups of related threads, referred to herein as a warp. In an embodiment, a warp comprises 32 related threads that may be executed in parallel. Cooperating threads may refer to a plurality of threads including instructions to perform the task and that may exchange data through shared memory. Threads and cooperating threads are described in more detail in conjunction with FIG. 11.

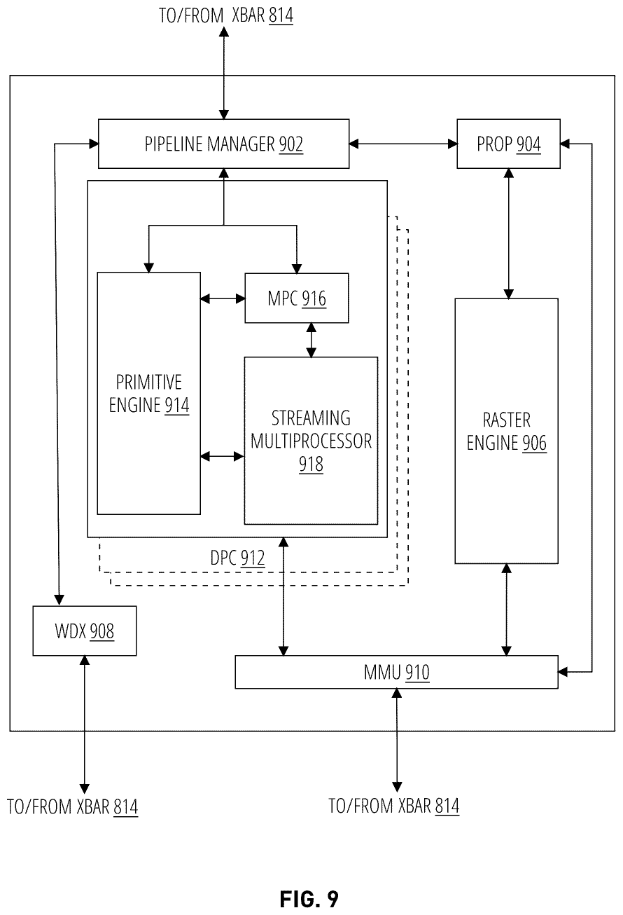

FIG. 9 depicts a general processing cluster 822 of the parallel processing unit 802 of FIG. 8, in accordance with an embodiment. As shown in FIG. 9, each general processing cluster 822 includes a number of hardware units for processing tasks. In an embodiment, each general processing cluster 822 includes a pipeline manager 902, a pre-raster operations unit 904, a raster engine 906, a work distribution crossbar 908, a memory management unit 910, and one or more data processing cluster 912. It will be appreciated that the general processing cluster 822 of FIG. 9 may include other hardware units in lieu of or in addition to the units shown in FIG. 9.

In an embodiment, the operation of the general processing cluster 822 is controlled by the pipeline manager 902. The pipeline manager 902 manages the configuration of the one or more data processing cluster 912 modules for processing tasks allocated to the general processing cluster 822. In an embodiment, the pipeline manager 902 may configure at least one of the one or more data processing cluster 912 modules to implement at least a portion of a graphics rendering pipeline. For example, a data processing cluster 912 may be configured to execute a vertex shader program on the programmable streaming multiprocessor 918. The pipeline manager 902 may also be configured to route packets received from the work distribution unit 810 to the appropriate logical units within the general processing cluster 822. For example, some packets may be routed to fixed function hardware units in the pre-raster operations unit 904 and/or raster engine 906 while other packets may be routed to the data processing cluster 912 modules for processing by the primitive engine 914 or the streaming multiprocessor 918. In an embodiment, the pipeline manager 902 may configure at least one of the one or more data processing cluster 912 modules to implement a neural network model and/or a computing pipeline.

The pre-raster operations unit 904 is configured to route data generated by the raster engine 906 and the data processing cluster 912 modules to a Raster Operations (ROP) unit, described in more detail in conjunction with FIG. 10. The pre-raster operations unit 904 may also be configured to perform optimizations for color blending, organize pixel data, perform address translations, and the like.

The raster engine 906 includes a number of fixed function hardware units configured to perform various raster operations. In an embodiment, the raster engine 906 includes a setup engine, a coarse raster engine, a culling engine, a clipping engine, a fine raster engine, and a tile coalescing engine. The setup engine receives transformed vertices and generates plane equations associated with the geometric primitive defined by the vertices. The plane equations are transmitted to the coarse raster engine to generate coverage information (e.g., an x, y coverage mask for a tile) for the primitive. The output of the coarse raster engine is transmitted to the culling engine where fragments associated with the primitive that fail a z-test are culled, and transmitted to a clipping engine where fragments lying outside a viewing frustum are clipped. Those fragments that survive clipping and culling may be passed to the fine raster engine to generate attributes for the pixel fragments based on the plane equations generated by the setup engine. The output of the raster engine 906 comprises fragments to be processed, for example, by a fragment shader implemented within a data processing cluster 912.

Each data processing cluster 912 included in the general processing cluster 822 includes an M-pipe controller 916, a primitive engine 914, and one or more streaming multiprocessor 918 modules. The M-pipe controller 916 controls the operation of the data processing cluster 912, routing packets received from the pipeline manager 902 to the appropriate units in the data processing cluster 912. For example, packets associated with a vertex may be routed to the primitive engine 914, which is configured to fetch vertex attributes associated with the vertex from the memory 820. In contrast, packets associated with a shader program may be transmitted to the streaming multiprocessor 918.

The streaming multiprocessor 918 comprises a programmable streaming processor that is configured to process tasks represented by a number of threads. Each streaming multiprocessor 918 is multi-threaded and configured to execute a plurality of threads (e.g., 32 threads) from a particular group of threads concurrently. In an embodiment, the streaming multiprocessor 918 implements a Single-Instruction, Multiple-Data (SIMD) architecture where each thread in a group of threads (e.g., a warp) is configured to process a different set of data based on the same set of instructions. All threads in the group of threads execute the same instructions. In another embodiment, the streaming multiprocessor 918 implements a Single-Instruction, Multiple Thread (SIMT) architecture where each thread in a group of threads is configured to process a different set of data based on the same set of instructions, but where individual threads in the group of threads are allowed to diverge during execution. In an embodiment, a program counter, call stack, and execution state is maintained for each warp, enabling concurrency between warps and serial execution within warps when threads within the warp diverge. In another embodiment, a program counter, call stack, and execution state is maintained for each individual thread, enabling equal concurrency between all threads, within and between warps. When execution state is maintained for each individual thread, threads executing the same instructions may be converged and executed in parallel for maximum efficiency. The streaming multiprocessor 918 will be described in more detail below in conjunction with FIG. 11.

The memory management unit 910 provides an interface between the general processing cluster 822 and the memory partition unit 824. The memory management unit 910 may provide translation of virtual addresses into physical addresses, memory protection, and arbitration of memory requests. In an embodiment, the memory management unit 910 provides one or more translation lookaside buffers (TLBs) for performing translation of virtual addresses into physical addresses in the memory 820.

FIG. 10 depicts a memory partition unit 824 of the parallel processing unit 802 of FIG. 8, in accordance with an embodiment. As shown in FIG. 10, the memory partition unit 824 includes a raster operations unit 1002, a level two cache 1004, and a memory interface 1006. The memory interface 1006 is coupled to the memory 820. Memory interface 1006 may implement 32, 64, 128, 1024-bit data buses, or the like, for high-speed data transfer. In an embodiment, the parallel processing unit 802 incorporates U memory interface 1006 modules, one memory interface 1006 per pair of memory partition unit 824 modules, where each pair of memory partition unit 824 modules is connected to a corresponding memory 820 device. For example, parallel processing unit 802 may be connected to up to Y memory 820 devices, such as high bandwidth memory stacks or graphics double-data-rate, version 5, synchronous dynamic random access memory, or other types of persistent storage.

In an embodiment, the memory interface 1006 implements an HBM2 memory interface and Y equals half U. In an embodiment, the HBM2 memory stacks are located on the same physical package as the parallel processing unit 802, providing substantial power and area savings compared with conventional GDDR5 SDRAM systems. In an embodiment, each HBM2 stack includes four memory dies and Y equals 4, with HBM2 stack including two 128-bit channels per die for a total of 8 channels and a data bus width of 1024 bits.

In an embodiment, the memory 820 supports Single-Error Correcting Double-Error Detecting (SECDED) Error Correction Code (ECC) to protect data. ECC provides higher reliability for compute applications that are sensitive to data corruption. Reliability is especially important in large-scale cluster computing environments where parallel processing unit 802 modules process very large datasets and/or run applications for extended periods.

In an embodiment, the parallel processing unit 802 implements a multi-level memory hierarchy. In an embodiment, the memory partition unit 824 supports a unified memory to provide a single unified virtual address space for CPU and parallel processing unit 802 memory, enabling data sharing between virtual memory systems. In an embodiment the frequency of accesses by a parallel processing unit 802 to memory located on other processors is traced to ensure that memory pages are moved to the physical memory of the parallel processing unit 802 that is accessing the pages more frequently. In an embodiment, the NVLink 816 supports address translation services allowing the parallel processing unit 802 to directly access a CPU's page tables and providing full access to CPU memory by the parallel processing unit 802.

In an embodiment, copy engines transfer data between multiple parallel processing unit 802 modules or between parallel processing unit 802 modules and CPUs. The copy engines can generate page faults for addresses that are not mapped into the page tables. The memory partition unit 824 can then service the page faults, mapping the addresses into the page table, after which the copy engine can perform the transfer. In a conventional system, memory is pinned (e.g., non-pageable) for multiple copy engine operations between multiple processors, substantially reducing the available memory. With hardware page faulting, addresses can be passed to the copy engines without worrying if the memory pages are resident, and the copy process is transparent.

Data from the memory 820 or other system memory may be fetched by the memory partition unit 824 and stored in the level two cache 1004, which is located on-chip and is shared between the various general processing cluster 822 modules. As shown, each memory partition unit 824 includes a portion of the level two cache 1004 associated with a corresponding memory 820 device. Lower level caches may then be implemented in various units within the general processing cluster 822 modules. For example, each of the streaming multiprocessor 918 modules may implement an L1 cache. The L1 cache is private memory that is dedicated to a particular streaming multiprocessor 918. Data from the level two cache 1004 may be fetched and stored in each of the L1 caches for processing in the functional units of the streaming multiprocessor 918 modules. The level two cache 1004 is coupled to the memory interface 1006 and the crossbar 814.

The raster operations unit 1002 performs graphics raster operations related to pixel color, such as color compression, pixel blending, and the like. The raster operations unit 1002 also implements depth testing in conjunction with the raster engine 906, receiving a depth for a sample location associated with a pixel fragment from the culling engine of the raster engine 906. The depth is tested against a corresponding depth in a depth buffer for a sample location associated with the fragment. If the fragment passes the depth test for the sample location, then the raster operations unit 1002 updates the depth buffer and transmits a result of the depth test to the raster engine 906. It will be appreciated that the number of partition memory partition unit 824 modules may be different than the number of general processing cluster 822 modules and, therefore, each raster operations unit 1002 may be coupled to each of the general processing cluster 822 modules. The raster operations unit 1002 tracks packets received from the different general processing cluster 822 modules and determines which general processing cluster 1 that a result generated by the raster operations unit 1002 is routed to through the crossbar 814. Although the raster operations unit 1002 is included within the memory partition unit 824 in FIG. 10, in other embodiment, the raster operations unit 1002 may be outside of the memory partition unit 824. For example, the raster operations unit 1002 may reside in the general processing cluster 822 or another unit.

FIG. 11 illustrates the streaming multiprocessor 918 of FIG. 9, in accordance with an embodiment. As shown in FIG. 11, the streaming multiprocessor 918 includes an instruction cache 1102, one or more scheduler unit 1104 modules (e.g., such as scheduler unit 808), a register file 1106, one or more processing core 1108 modules, one or more special function unit 1110 modules, one or more load/store unit 1112 modules, an interconnect network 1114, and a shared memory/L1 cache 1116.

As described above, the work distribution unit 810 dispatches tasks for execution on the general processing cluster 822 modules of the parallel processing unit 802. The tasks are allocated to a particular data processing cluster 912 within a general processing cluster 822 and, if the task is associated with a shader program, the task may be allocated to a streaming multiprocessor 918. The scheduler unit 808 receives the tasks from the work distribution unit 810 and manages instruction scheduling for one or more thread blocks assigned to the streaming multiprocessor 918. The scheduler unit 1104 schedules thread blocks for execution as warps of parallel threads, where each thread block is allocated at least one warp. In an embodiment, each warp executes 32 threads. The scheduler unit 1104 may manage a plurality of different thread blocks, allocating the warps to the different thread blocks and then dispatching instructions from the plurality of different cooperative groups to the various functional units (e.g., core 1108 modules, special function unit 1110 modules, and load/store unit 1112 modules) during each clock cycle.

Cooperative Groups is a programming model for organizing groups of communicating threads that allows developers to express the granularity at which threads are communicating, enabling the expression of richer, more efficient parallel decompositions. Cooperative launch APIs support synchronization amongst thread blocks for the execution of parallel algorithms. Conventional programming models provide a single, simple construct for synchronizing cooperating threads: a barrier across all threads of a thread block (e.g., the syncthreads( ) function). However, programmers would often like to define groups of threads at smaller than thread block granularities and synchronize within the defined groups to enable greater performance, design flexibility, and software reuse in the form of collective group-wide function interfaces.

Cooperative Groups enables programmers to define groups of threads explicitly at sub-block (e.g., as small as a single thread) and multi-block granularities, and to perform collective operations such as synchronization on the threads in a cooperative group. The programming model supports clean composition across software boundaries, so that libraries and utility functions can synchronize safely within their local context without having to make assumptions about convergence. Cooperative Groups primitives enable new patterns of cooperative parallelism, including producer-consumer parallelism, opportunistic parallelism, and global synchronization across an entire grid of thread blocks.

A dispatch 1118 unit is configured within the scheduler unit 1104 to transmit instructions to one or more of the functional units. In one embodiment, the scheduler unit 1104 includes two dispatch 1118 units that enable two different instructions from the same warp to be dispatched during each clock cycle. In alternative embodiments, each scheduler unit 1104 may include a single dispatch 1118 unit or additional dispatch 1118 units.

Each streaming multiprocessor 918 includes a register file 1106 that provides a set of registers for the functional units of the streaming multiprocessor 918. In an embodiment, the register file 1106 is divided between each of the functional units such that each functional unit is allocated a dedicated portion of the register file 1106. In another embodiment, the register file 1106 is divided between the different warps being executed by the streaming multiprocessor 918. The register file 1106 provides temporary storage for operands connected to the data paths of the functional units.

Each streaming multiprocessor 918 comprises L processing core 1108 modules. In an embodiment, the streaming multiprocessor 918 includes a large number (e.g., 128, etc.) of distinct processing core 1108 modules. Each core 1108 may include a fully-pipelined, single-precision, double-precision, and/or mixed precision processing unit that includes a floating point arithmetic logic unit and an integer arithmetic logic unit. In an embodiment, the floating point arithmetic logic units implement the IEEE 754-2008 standard for floating point arithmetic. In an embodiment, the core 1108 modules include 64 single-precision (32-bit) floating point cores, 64 integer cores, 32 double-precision (64-bit) floating point cores, and 8 tensor cores.

Tensor cores configured to perform matrix operations, and, in an embodiment, one or more tensor cores are included in the core 1108 modules. In particular, the tensor cores are configured to perform deep learning matrix arithmetic, such as convolution operations for neural network training and inferencing. In an embodiment, each tensor core operates on a 4×4 matrix and performs a matrix multiply and accumulate operation D=A′B+C, where A, B, C, and D are 4×4 matrices.

In an embodiment, the matrix multiply inputs A and B are 16-bit floating point matrices, while the accumulation matrices C and D may be 16-bit floating point or 32-bit floating point matrices. Tensor Cores operate on 16-bit floating point input data with 32-bit floating point accumulation. The 16-bit floating point multiply requires 64 operations and results in a full precision product that is then accumulated using 32-bit floating point addition with the other intermediate products for a 4×4×4 matrix multiply. In practice, Tensor Cores are used to perform much larger two-dimensional or higher dimensional matrix operations, built up from these smaller elements. An API, such as CUDA 9 C++ API, exposes specialized matrix load, matrix multiply and accumulate, and matrix store operations to efficiently use Tensor Cores from a CUDA-C++ program. At the CUDA level, the warp-level interface assumes 16×16 size matrices spanning all 32 threads of the warp.

Each streaming multiprocessor 918 also comprises M special function unit 1110 modules that perform special functions (e.g., attribute evaluation, reciprocal square root, and the like). In an embodiment, the special function unit 1110 modules may include a tree traversal unit configured to traverse a hierarchical tree data structure. In an embodiment, the special function unit 1110 modules may include texture unit configured to perform texture map filtering operations. In an embodiment, the texture units are configured to load texture maps (e.g., a 2D array of texels) from the memory 820 and sample the texture maps to produce sampled texture values for use in shader programs executed by the streaming multiprocessor 918. In an embodiment, the texture maps are stored in the shared memory/L1 cache 1116. The texture units implement texture operations such as filtering operations using mip-maps (e.g., texture maps of varying levels of detail). In an embodiment, each streaming multiprocessor 918 includes two texture units.

Each streaming multiprocessor 918 also comprises N load/store unit 1112 modules that implement load and store operations between the shared memory/L1 cache 1116 and the register file 1106. Each streaming multiprocessor 918 includes an interconnect network 1114 that connects each of the functional units to the register file 1106 and the load/store unit 1112 to the register file 1106 and shared memory/L1 cache 1116. In an embodiment, the interconnect network 1114 is a crossbar that can be configured to connect any of the functional units to any of the registers in the register file 1106 and connect the load/store unit 1112 modules to the register file 1106 and memory locations in shared memory/L1 cache 1116.

The shared memory/L1 cache 1116 is an array of on-chip memory that allows for data storage and communication between the streaming multiprocessor 918 and the primitive engine 914 and between threads in the streaming multiprocessor 918. In an embodiment, the shared memory/L1 cache 1116 comprises 128 KB of storage capacity and is in the path from the streaming multiprocessor 918 to the memory partition unit 824. The shared memory/L1 cache 1116 can be used to cache reads and writes. One or more of the shared memory/L1 cache 1116, level two cache 1004, and memory 820 are backing stores.

Combining data cache and shared memory functionality into a single memory block provides the best overall performance for both types of memory accesses. The capacity is usable as a cache by programs that do not use shared memory. For example, if shared memory is configured to use half of the capacity, texture and load/store operations can use the remaining capacity. Integration within the shared memory/L1 cache 1116 enables the shared memory/L1 cache 1116 to function as a high-throughput conduit for streaming data while simultaneously providing high-bandwidth and low-latency access to frequently reused data.

When configured for general purpose parallel computation, a simpler configuration can be used compared with graphics processing. Specifically, the fixed function graphics processing units shown in FIG. 8, are bypassed, creating a much simpler programming model. In the general purpose parallel computation configuration, the work distribution unit 810 assigns and distributes blocks of threads directly to the data processing cluster 912 modules. The threads in a block execute the same program, using a unique thread ID in the calculation to ensure each thread generates unique results, using the streaming multiprocessor 918 to execute the program and perform calculations, shared memory/L1 cache 1116 to communicate between threads, and the load/store unit 1112 to read and write global memory through the shared memory/L1 cache 1116 and the memory partition unit 824. When configured for general purpose parallel computation, the streaming multiprocessor 918 can also write commands that the scheduler unit 808 can use to launch new work on the data processing cluster 912 modules.

The parallel processing unit 802 may be included in a desktop computer, a laptop computer, a tablet computer, servers, supercomputers, a smart-phone (e.g., a wireless, hand-held device), personal digital assistant (PDA), a digital camera, a vehicle, a head mounted display, a hand-held electronic device, and the like. In an embodiment, the parallel processing unit 802 is embodied on a single semiconductor substrate. In another embodiment, the parallel processing unit 802 is included in a system-on-a-chip (SoC) along with one or more other devices such as additional parallel processing unit 802 modules, the memory 820, a reduced instruction set computer (RISC) CPU, a memory management unit (MMU), a digital-to-analog converter (DAC), and the like.

In an embodiment, the parallel processing unit 802 may be included on a graphics card that includes one or more memory devices. The graphics card may be configured to interface with a PCIe slot on a motherboard of a desktop computer. In yet another embodiment, the parallel processing unit 802 may be an integrated graphics processing unit (iGPU) or parallel processor included in the chipset of the motherboard.

Systems with multiple GPUs and CPUs are used in a variety of industries as developers expose and leverage more parallelism in applications such as artificial intelligence computing. High-performance GPU-accelerated systems with tens to many thousands of compute nodes are deployed in data centers, research facilities, and supercomputers to solve ever larger problems. As the number of processing devices within the high-performance systems increases, the communication and data transfer mechanisms need to scale to support the increased bandwidth.

FIG. 12 is a conceptual diagram of a processing system implemented using the parallel processing unit 802 of FIG. 8, in accordance with an embodiment. The processing system includes a central processing unit 1202, a switch 1204, and multiple parallel processing unit 802 modules each and respective memory 820 modules. The switch 1204 is depicted with dashed lines, indicating that it is optional in some embodiments.

The NVLink 816 provides high-speed communication links between each of the parallel processing unit 802 modules. Although a particular number of NVLink 816 and interconnect 818 connections are illustrated in FIG. 12, the number of connections to each parallel processing unit 802 and the central processing unit 1202 may vary. The switch 1204 interfaces between the interconnect 818 and the central processing unit 1202. The parallel processing unit 802 modules, memory 820 modules, and NVLink 816 connections may be situated on a single semiconductor platform to form a parallel processing module 1206. In an embodiment, the switch 1204 supports two or more protocols to interface between various different connections and/or links.

In another embodiment (not shown), the NVLink 816 provides one or more high-speed communication links between each of the parallel processing unit modules (parallel processing unit 802, parallel processing unit 802, parallel processing unit 802, and parallel processing unit 802) and the central processing unit 1202 and the switch 1204 (when present) interfaces between the interconnect 818 and each of the parallel processing unit modules. The parallel processing unit modules, memory 820 modules, and interconnect 818 may be situated on a single semiconductor platform to form a parallel processing module 1206. In yet another embodiment (not shown), the interconnect 818 provides one or more communication links between each of the parallel processing unit modules and the central processing unit 1202 and the switch 1204 interfaces between each of the parallel processing unit modules using the NVLink 816 to provide one or more high-speed communication links between the parallel processing unit modules. In another embodiment (not shown), the NVLink 816 provides one or more high-speed communication links between the parallel processing unit modules and the central processing unit 1202 through the switch 1204. In yet another embodiment (not shown), the interconnect 818 provides one or more communication links between each of the parallel processing unit modules directly. One or more of the NVLink 816 high-speed communication links may be implemented as a physical NVLink interconnect or either an on-chip or on-die interconnect using the same protocol as the NVLink 816.

In the context of the present description, a single semiconductor platform may refer to a sole unitary semiconductor-based integrated circuit fabricated on a die or chip. It should be noted that the term single semiconductor platform may also refer to multi-chip modules with increased connectivity which simulate on-chip operation and make substantial improvements over utilizing a conventional bus implementation. Of course, the various circuits or devices may also be situated separately or in various combinations of semiconductor platforms per the desires of the user. Alternately, the parallel processing module 1206 may be implemented as a circuit board substrate and each of the parallel processing unit modules and/or memory 820 modules may be packaged devices. In an embodiment, the central processing unit 1202, switch 1204, and the parallel processing module 1206 are situated on a single semiconductor platform.

In an embodiment, each parallel processing unit module includes six NVLink 816 interfaces (as shown in FIG. 12, five NVLink 816 interfaces are included for each parallel processing unit module). The NVLink 816 may be operated exclusively for PPU-to-PPU communication as shown in FIG. 12, or some combination of PPU-to-PPU and PPU-to-CPU, when the central processing unit 1202 also includes one or more NVLink 816 interfaces.

In an embodiment, the NVLink 816 allows direct load/store/atomic access from the central processing unit 1202 to each parallel processing unit module's memory 820. In an embodiment, the NVLink 816 supports coherency operations, allowing data read from the memory 820 modules to be stored in the cache hierarchy of the central processing unit 1202, reducing cache access latency for the central processing unit 1202. In an embodiment, the NVLink 816 includes support for Address Translation Services (ATS), enabling the parallel processing unit module to directly access page tables within the central processing unit 1202. One or more of the NVLink 816 may also be configured to operate in a low-power mode.

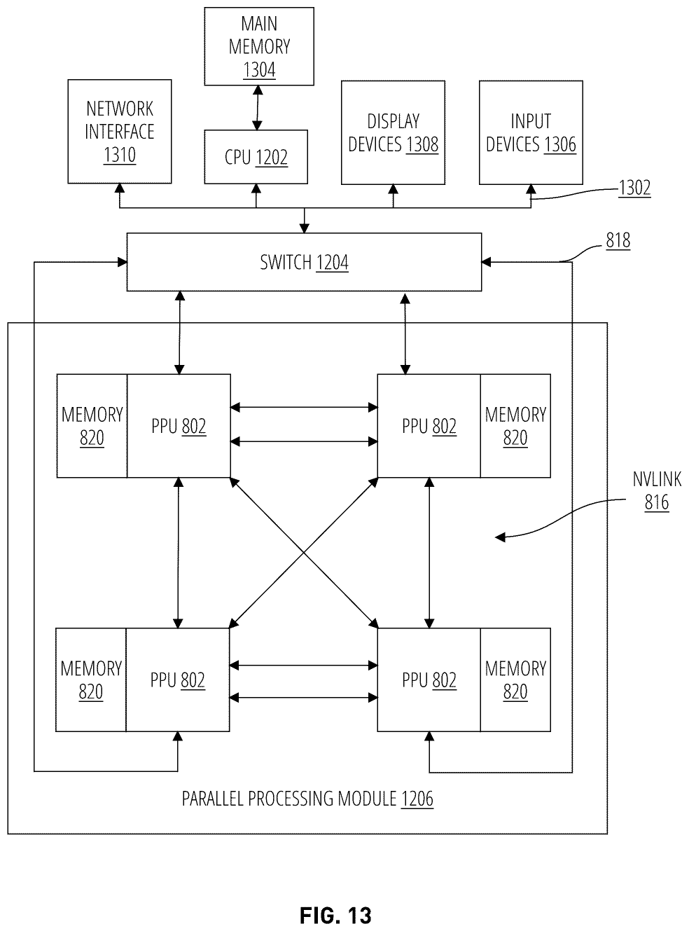

FIG. 13 depicts an exemplary processing system in which the various architecture and/or functionality of the various previous embodiments may be implemented. As shown, an exemplary processing system is provided including at least one central processing unit 1202 that is connected to a communications bus 1302. The communication communications bus 1302 may be implemented using any suitable protocol, such as PCI (Peripheral Component Interconnect), PCI-Express, AGP (Accelerated Graphics Port), HyperTransport, or any other bus or point-to-point communication protocol(s). The exemplary processing system also includes a main memory 1304. Control logic (software) and data are stored in the main memory 1304 which may take the form of random access memory (RAM), and for simplicity of illustration may be understood to comprise other forms of bulk storage (e.g., non-volatile memory technologies).

The exemplary processing system also includes input devices 1306, the parallel processing module 1206, and display devices 1308, e.g. a conventional CRT (cathode ray tube), LCD (liquid crystal display), LED (light emitting diode), plasma display or the like. User input may be received from the input devices 1306, e.g., keyboard, mouse, touchpad, microphone, and the like. Each of the foregoing modules and/or devices may even be situated on a single semiconductor platform to form the exemplary processing system. Alternately, the various modules may also be situated separately or in various combinations of semiconductor platforms per the desires of the user.

Further, the exemplary processing system may be coupled to a network (e.g., a telecommunications network, local area network (LAN), wireless network, wide area network (WAN) such as the Internet, peer-to-peer network, cable network, or the like) through a network interface 1310 for communication purposes.

The exemplary processing system may also include a secondary storage (not shown). The secondary storage includes, for example, a hard disk drive and/or a removable storage drive, representing a floppy disk drive, a magnetic tape drive, a compact disk drive, digital versatile disk (DVD) drive, recording device, universal serial bus (USB) flash memory. The removable storage drive reads from and/or writes to a removable storage unit in a well-known manner.

Computer programs, or computer control logic algorithms, may be stored in the main memory 1304 and/or the secondary storage. Such computer programs, when executed, enable the exemplary processing system to perform various functions. The main memory 1304, the storage, and/or any other storage are possible examples of computer-readable media (volatile and/or non-volatile, depending on the implementation).

The architecture and/or functionality of the various previous figures may be implemented in the context of a general computer system, a circuit board system, a game console system dedicated for entertainment purposes, an application-specific system, and/or any other desired system. For example, the exemplary processing system may take the form of a desktop computer, a laptop computer, a tablet computer, servers, supercomputers, a smart-phone (e.g., a wireless, hand-held device), personal digital assistant (PDA), a digital camera, a vehicle, a head mounted display, a hand-held electronic device, a mobile phone device, a television, workstation, game consoles, embedded system, and/or any other type of logic.

While various embodiments have been described above, it should be understood that they have been presented by way of example only, and not limitation. Thus, the breadth and scope of a preferred embodiment should not be limited by any of the above-described exemplary embodiments, but should be defined only in accordance with the following claims and their equivalents.

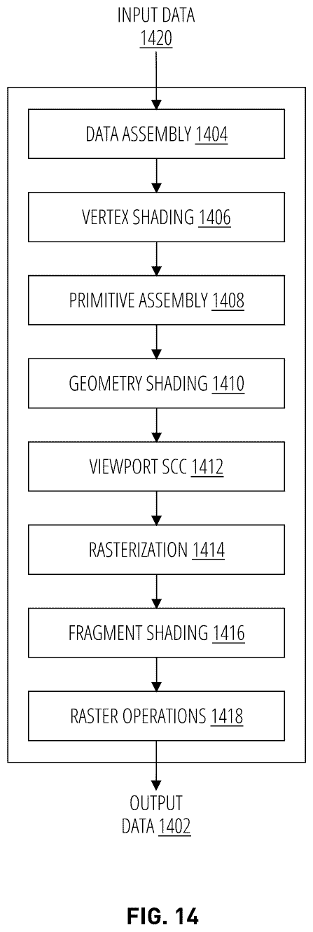

FIG. 14 is a conceptual diagram of a graphics processing pipeline implemented by the parallel processing unit 802 of FIG. 8, in accordance with an embodiment. In an embodiment, the parallel processing unit 802 comprises a graphics processing unit (GPU). The parallel processing unit 802 is configured to receive commands that specify shader programs for processing graphics data. Graphics data may be defined as a set of primitives such as points, lines, triangles, quads, triangle strips, and the like. Typically, a primitive includes data that specifies a number of vertices for the primitive (e.g., in a model-space coordinate system) as well as attributes associated with each vertex of the primitive. The parallel processing unit 802 can be configured to process the graphics primitives to generate a frame buffer (e.g., pixel data for each of the pixels of the display).

An application writes model data for a scene (e.g., a collection of vertices and attributes) to a memory such as a system memory or memory 820. The model data defines each of the objects that may be visible on a display. The application then makes an API call to the driver kernel that requests the model data to be rendered and displayed. The driver kernel reads the model data and writes commands to the one or more streams to perform operations to process the model data. The commands may reference different shader programs to be implemented on the streaming multiprocessor 918 modules of the parallel processing unit 802 including one or more of a vertex shader, hull shader, domain shader, geometry shader, and a pixel shader. For example, one or more of the streaming multiprocessor 918 modules may be configured to execute a vertex shader program that processes a number of vertices defined by the model data. In an embodiment, the different streaming multiprocessor 918 modules may be configured to execute different shader programs concurrently. For example, a first subset of streaming multiprocessor 918 modules may be configured to execute a vertex shader program while a second subset of streaming multiprocessor 918 modules may be configured to execute a pixel shader program. The first subset of streaming multiprocessor 918 modules processes vertex data to produce processed vertex data and writes the processed vertex data to the level two cache 1004 and/or the memory 820. After the processed vertex data is rasterized (e.g., transformed from three-dimensional data into two-dimensional data in screen space) to produce fragment data, the second subset of streaming multiprocessor 918 modules executes a pixel shader to produce processed fragment data, which is then blended with other processed fragment data and written to the frame buffer in memory 820. The vertex shader program and pixel shader program may execute concurrently, processing different data from the same scene in a pipelined fashion until all of the model data for the scene has been rendered to the frame buffer. Then, the contents of the frame buffer are transmitted to a display controller for display on a display device.

The graphics processing pipeline is an abstract flow diagram of the processing steps implemented to generate 2D computer-generated images from 3D geometry data. As is well-known, pipeline architectures may perform long latency operations more efficiently by splitting up the operation into a plurality of stages, where the output of each stage is coupled to the input of the next successive stage. Thus, the graphics processing pipeline receives input data 601 that is transmitted from one stage to the next stage of the graphics processing pipeline to generate output data 1402. In an embodiment, the graphics processing pipeline may represent a graphics processing pipeline defined by the OpenGL® API. As an option, the graphics processing pipeline may be implemented in the context of the functionality and architecture of the previous Figures and/or any subsequent Figure(s).

As shown in FIG. 14, the graphics processing pipeline comprises a pipeline architecture that includes a number of stages. The stages include, but are not limited to, a data assembly 1404 stage, a vertex shading 1406 stage, a primitive assembly 1408 stage, a geometry shading 1410 stage, a viewport SCC 1412 stage, a rasterization 1414 stage, a fragment shading 1416 stage, and a raster operations 1418 stage. In an embodiment, the input data 1420 comprises commands that configure the processing units to implement the stages of the graphics processing pipeline and geometric primitives (e.g., points, lines, triangles, quads, triangle strips or fans, etc.) to be processed by the stages. The output data 1402 may comprise pixel data (e.g., color data) that is copied into a frame buffer or other type of surface data structure in a memory.

The data assembly 1404 stage receives the input data 1420 that specifies vertex data for high-order surfaces, primitives, or the like. The data assembly 1404 stage collects the vertex data in a temporary storage or queue, such as by receiving a command from the host processor that includes a pointer to a buffer in memory and reading the vertex data from the buffer. The vertex data is then transmitted to the vertex shading 1406 stage for processing.

The vertex shading 1406 stage processes vertex data by performing a set of operations (e.g., a vertex shader or a program) once for each of the vertices. Vertices may be, e.g., specified as a 4-coordinate vector (e.g., <x, y, z, w>) associated with one or more vertex attributes (e.g., color, texture coordinates, surface normal, etc.). The vertex shading 1406 stage may manipulate individual vertex attributes such as position, color, texture coordinates, and the like. In other words, the vertex shading 1406 stage performs operations on the vertex coordinates or other vertex attributes associated with a vertex. Such operations commonly including lighting operations (e.g., modifying color attributes for a vertex) and transformation operations (e.g., modifying the coordinate space for a vertex). For example, vertices may be specified using coordinates in an object-coordinate space, which are transformed by multiplying the coordinates by a matrix that translates the coordinates from the object-coordinate space into a world space or a normalized-device-coordinate (NCD) space. The vertex shading 1406 stage generates transformed vertex data that is transmitted to the primitive assembly 1408 stage.

The primitive assembly 1408 stage collects vertices output by the vertex shading 1406 stage and groups the vertices into geometric primitives for processing by the geometry shading 1410 stage. For example, the primitive assembly 1408 stage may be configured to group every three consecutive vertices as a geometric primitive (e.g., a triangle) for transmission to the geometry shading 1410 stage. In some embodiments, specific vertices may be reused for consecutive geometric primitives (e.g., two consecutive triangles in a triangle strip may share two vertices). The primitive assembly 1408 stage transmits geometric primitives (e.g., a collection of associated vertices) to the geometry shading 1410 stage.

The geometry shading 1410 stage processes geometric primitives by performing a set of operations (e.g., a geometry shader or program) on the geometric primitives. Tessellation operations may generate one or more geometric primitives from each geometric primitive. In other words, the geometry shading 1410 stage may subdivide each geometric primitive into a finer mesh of two or more geometric primitives for processing by the rest of the graphics processing pipeline. The geometry shading 1410 stage transmits geometric primitives to the viewport SCC 1412 stage.

In an embodiment, the graphics processing pipeline may operate within a streaming multiprocessor and the vertex shading 1406 stage, the primitive assembly 1408 stage, the geometry shading 1410 stage, the fragment shading 1416 stage, and/or hardware/software associated therewith, may sequentially perform processing operations. Once the sequential processing operations are complete, in an embodiment, the viewport SCC 1412 stage may utilize the data. In an embodiment, primitive data processed by one or more of the stages in the graphics processing pipeline may be written to a cache (e.g. L1 cache, a vertex cache, etc.). In this case, in an embodiment, the viewport SCC 1412 stage may access the data in the cache. In an embodiment, the viewport SCC 1412 stage and the rasterization 1414 stage are implemented as fixed function circuitry.

The viewport SCC 1412 stage performs viewport scaling, culling, and clipping of the geometric primitives. Each surface being rendered to is associated with an abstract camera position. The camera position represents a location of a viewer looking at the scene and defines a viewing frustum that encloses the objects of the scene. The viewing frustum may include a viewing plane, a rear plane, and four clipping planes. Any geometric primitive entirely outside of the viewing frustum may be culled (e.g., discarded) because the geometric primitive will not contribute to the final rendered scene. Any geometric primitive that is partially inside the viewing frustum and partially outside the viewing frustum may be clipped (e.g., transformed into a new geometric primitive that is enclosed within the viewing frustum. Furthermore, geometric primitives may each be scaled based on a depth of the viewing frustum. All potentially visible geometric primitives are then transmitted to the rasterization 1414 stage.

The rasterization 1414 stage converts the 3D geometric primitives into 2D fragments (e.g. capable of being utilized for display, etc.). The rasterization 1414 stage may be configured to utilize the vertices of the geometric primitives to setup a set of plane equations from which various attributes can be interpolated. The rasterization 1414 stage may also compute a coverage mask for a plurality of pixels that indicates whether one or more sample locations for the pixel intercept the geometric primitive. In an embodiment, z-testing may also be performed to determine if the geometric primitive is occluded by other geometric primitives that have already been rasterized. The rasterization 1414 stage generates fragment data (e.g., interpolated vertex attributes associated with a particular sample location for each covered pixel) that are transmitted to the fragment shading 1416 stage.

The fragment shading 1416 stage processes fragment data by performing a set of operations (e.g., a fragment shader or a program) on each of the fragments. The fragment shading 1416 stage may generate pixel data (e.g., color values) for the fragment such as by performing lighting operations or sampling texture maps using interpolated texture coordinates for the fragment. The fragment shading 1416 stage generates pixel data that is transmitted to the raster operations 1418 stage.

The raster operations 1418 stage may perform various operations on the pixel data such as performing alpha tests, stencil tests, and blending the pixel data with other pixel data corresponding to other fragments associated with the pixel. When the raster operations 1418 stage has finished processing the pixel data (e.g., the output data 1402), the pixel data may be written to a render target such as a frame buffer, a color buffer, or the like.

It will be appreciated that one or more additional stages may be included in the graphics processing pipeline in addition to or in lieu of one or more of the stages described above. Various implementations of the abstract graphics processing pipeline may implement different stages. Furthermore, one or more of the stages described above may be excluded from the graphics processing pipeline in some embodiments (such as the geometry shading 1410 stage). Other types of graphics processing pipelines are contemplated as being within the scope of the present disclosure. Furthermore, any of the stages of the graphics processing pipeline may be implemented by one or more dedicated hardware units within a graphics processor such as parallel processing unit 802. Other stages of the graphics processing pipeline may be implemented by programmable hardware units such as the streaming multiprocessor 918 of the parallel processing unit 802.

The graphics processing pipeline may be implemented via an application executed by a host processor, such as a CPU. In an embodiment, a device driver may implement an application programming interface (API) that defines various functions that can be utilized by an application in order to generate graphical data for display. The device driver is a software program that includes a plurality of instructions that control the operation of the parallel processing unit 802. The API provides an abstraction for a programmer that lets a programmer utilize specialized graphics hardware, such as the parallel processing unit 802, to generate the graphical data without requiring the programmer to utilize the specific instruction set for the parallel processing unit 802. The application may include an API call that is routed to the device driver for the parallel processing unit 802. The device driver interprets the API call and performs various operations to respond to the API call. In some instances, the device driver may perform operations by executing instructions on the CPU. In other instances, the device driver may perform operations, at least in part, by launching operations on the parallel processing unit 802 utilizing an input/output interface between the CPU and the parallel processing unit 802. In an embodiment, the device driver is configured to implement the graphics processing pipeline utilizing the hardware of the parallel processing unit 802.

Various programs may be executed within the parallel processing unit 802 in order to implement the various stages of the graphics processing pipeline. For example, the device driver may launch a kernel on the parallel processing unit 802 to perform the vertex shading 1406 stage on one streaming multiprocessor 918 (or multiple streaming multiprocessor 918 modules). The device driver (or the initial kernel executed by the parallel processing unit 802) may also launch other kernels on the parallel processing unit 802 to perform other stages of the graphics processing pipeline, such as the geometry shading 1410 stage and the fragment shading 1416 stage. In addition, some of the stages of the graphics processing pipeline may be implemented on fixed unit hardware such as a rasterizer or a data assembler implemented within the parallel processing unit 802. It will be appreciated that results from one kernel may be processed by one or more intervening fixed function hardware units before being processed by a subsequent kernel on a streaming multiprocessor 918.

Edge-based optical proximity correction enables boundary information to be obtained efficiently during the optimization process execution runtime, including edges, line ends, jogs, notches, and other features. This is generally impractical to obtain with pixel-based optical proximity correction mechanisms. Level set-based methods may control boundaries globally but lack the ability to fine-tune specific locations.

The disclosed mechanisms generate optimization results with few or no mask rule constraints by explicitly controlling manufacturability through the velocity term vᵢ during optimization. Mask rules may be classified into two categories. The first category of mask rules comprise spacing checks, such as minimum spacing, end of line spacing, jog to jog spacing, and special notch spacing, and width checks, such as minimum width check.

Let δ denote the distance vector between check pairs. The projection of δ along the y-direction is given by proj_{y}δ=(δ·j)j, where j is the unit vector in the y-direction. The projection along the x-direction is similarly defined.

Mask rule constraint-aware optimization may be enabled by controlling the velocity vᵢ as follows: v′ᵢ=vᵢ·τ(δ) where τ(δ) is a function related to δ, defined as: τ(δ)=σ(β(proj δ−D)).

Here, D is a constant related to the mask rule, and proj is the projection operator in either x or y direction, β is the steepness of sigmoid function ϕ(⋅). For the spacing and width check, when the distance proj δ is smaller than D, the velocity term rapidly decays to 0, preventing further reduction in the distance. When proj δ is greater than D, τ(δ) returns to 1, allowing normal optimization to proceed without interference. By controlling the velocity term based on the distance between check pairs and mask rule constraints, the disclosed mechanisms effectively incorporate mask rule constraints into the optimization process.

After obtaining the mask M through the rasterization process, a forward lithography model as parameterized in Eq. (1) may be applied to calculate the intensity I of an aerial image that produces the mask. To obtain a continuous-valued printed (resist) image Z, a sigmoid function ϕ(⋅) may be applied that scales the resist image parameterized by Eq. (2) into a continuous space: Z=σ(α(I−Iₜₕ)), where α is the steepness of σ(⋅), and Iₜₕ is the threshold intensity value.

To generate the backward gradients, the disclosed mechanisms may apply a combination of three loss determinations: L2 loss, process variation band (PVB) loss, and edge placement error (EPE) loss. The L2 loss and PVB loss are determined as:

$$L 2 = {‖ {Z}_{n o m} - T ‖}^{2} \qquad ( Eq . 7 )$$

$${L}_{p ν b} = {‖ {Z}_{max} - {Z}_{min} ‖}^{2} \qquad ( Eq . 8 )$$

For the EPE loss, measured points are sampled along the boundary of the target patterns, which includes a set of samples on horizontal edges (HS) and a set of samples on vertical edges (VS). A sigmoid function may then be applied to map the discrete EPE loss to a continuous-value domain. First, a distance between Zₙₒₘ and the target pattern T at the sampled points in VS and HS may be determined:

$${D}_{sumij} = \{ \begin{matrix}{\sum }_{k = j - {th}_{epe}}^{j + {th}_{epe}} {D}_{ik} , & if ( i , j ) ∈ HS \\ {\sum }_{k = i - {th}_{epe}}^{i + {th}_{epe}} {D}_{kj} , & if ( i , j ) ∈ VS\end{matrix} \qquad Eq . 9$$

where Dᵢₖ and Dₖⱼ represent the distances between the printed image and the target pattern, respectively, at the corresponding locations. Parameter thₑₚₑ is a threshold value that determines the neighborhood size for the distance calculation. D may be calculated as: D=(Zₙₒₘ−T)². The sigmoid function may be applied to the calculated distances to obtain the continuous-valued EPE loss as follows:

$${ℒ}_{e p e} = {\sum }_{( i , j ) ∈ HS ⋃ VS} \frac{1}{1 + {e}^{- γ {D}_{s u m i j}}} \qquad Eq . 10$$

where γ is a scaling factor that controls the steepness of the sigmoid function. The total loss function may then be determined by a weighted sum of the three individual loss components:

$${ℒ}_{total} = {w}_{1} {ℒ}_{2} + {w}_{2} {ℒ}_{p v b} + {w}_{3} {ℓ}_{e p e} \qquad Eq . 11$$

where w1, w2, and w3 are the weights assigned to each loss component, and may be empirically determined. The use of the sigmoid function in the edge placement error loss enables smooth integration of the edge placement error into the continuous-value domain, enabling efficient gradient-based optimization.

In the backward pass, the gradients of the total loss function with respect to the segment sᵢ may be determined by applying the chain rule:

$$\frac{\partial ℒ}{\partial {s}_{i}} = \frac{\partial ℒ}{\partial M} \cdot \frac{\partial M}{\partial {s}_{i}} = \frac{\partial ℒ}{\partial M} [ ⌊ \frac{{x}_{i 1} + {x}_{i 2}}{2} ⌋ , ⌊ \frac{{y}_{i 1} + {y}_{i 2}}{2} ⌋ ] \cdot {v}_{i} \qquad Eq . 12$$

where └⋅┘ is floor operation and

$$\frac{\partial ℒ}{\partial M} = {w}_{1} \frac{\partial {ℒ}_{2}}{\partial M} + {w}_{2} \frac{\partial {ℒ}_{p v b}}{\partial M} + {w}_{3} \frac{\partial {ℒ}_{e p e}}{\partial M} \qquad Eq . 13$$

For the L2 loss, the gradient may be calculated as:

$$\frac{\partial {ℒ}_{2}}{\partial M} = 2 \cdot ( Z - T ) ⊙ \frac{\partial Z}{\partial M} = 2 α \cdot \{ {H}^{′} ⊗ [ ( Z - T ) ⊙ Z ⊙ ( 1 - Z ) ⊙ ( M ⊗ H * ) ] + ( {H}^{′} ) * ⊗ [ ( Z - T ) ⊙ Z ⊙ ( 1 - Z ) ⊙ ( M ⊗ H ) ] \} \qquad Eq . 14$$

where the H′ is the flipped optical kernel set H, and the H* is the conjugate of H. Similarly, for the PVB loss, the gradient may be calculated as:

$$\frac{\partial {ℒ}_{p v b}}{\partial M} = 2 \times ( {Z}_{min} - {Z}_{max} ) ⊙ ( \frac{\partial {Z}_{min}}{\partial M} - \frac{\partial {Z}_{max}}{\partial M} ) \qquad Eq . 14$$

The derivation of ∂Zₘᵢₙ/∂M and ∂Zₘₐₓ/∂M is similar to that of ∂Z/∂M in eq. (13). For the EPE loss, the gradient may be calculated by summarizing the gradients at the measure points (i, j):

$$\frac{\partial {ℒ}_{e p e}}{\partial M} = {\sum }_{( i , j ) ∈ HS ⋃ VS} \frac{\partial {ℒ}_{e p e}}{\partial {D}_{s u m i j}} \cdot \frac{\partial {D}_{s u m i j}}{\partial M} \qquad Eq . 15$$

$$where$$

$$\frac{\partial {ℒ}_{e p e}}{\partial {D}_{s u m i j}} = γ \cdot ( \frac{1}{1 + {e}^{- γ {D}_{s u m i j}}} ) ( 1 - \frac{1}{1 + {e}^{- γ {D}_{s u m i j}}} ) \qquad Eq . 16$$

$$and$$

$$\frac{{D}_{sumij}}{\partial M} = \{ \begin{matrix}{\sum }_{k = j - {th}_{epe}}^{j + {th}_{epe}} \frac{{D}_{ik}}{\partial M} , & if ( i , j ) ∈ HS \\ {\sum }_{k = i - {th}_{epe}}^{i + {th}_{epe}} \frac{{D}_{kj}}{\partial M} , & if ( i , j ) ∈ VS\end{matrix} \qquad Eq . 17$$

with ∂Dᵢⱼ/∂M calculated as:

$$\frac{\partial {D}_{i j}}{\partial M} = \frac{\partial {( {Z}_{i j} - {T}_{i j} )}^{2}}{\partial M} = 2 ( {Z}_{ij} - {T}_{ij} ) \cdot \frac{\partial {Z}_{i j}}{\partial M} \qquad Eq . 18$$

Various functional operations described herein may be implemented in logic that is referred to using a noun or noun phrase reflecting said operation or function. For example, an association operation may be carried out by an “associator” or “correlator”. Likewise, switching may be carried out by a “switch”, selection by a “selector”, and so on. “Logic” refers to machine memory circuits and non-transitory machine readable media comprising machine-executable instructions (software and firmware), and/or circuitry (hardware) which by way of its material and/or material-energy configuration comprises control and/or procedural signals, and/or settings and values (such as resistance, impedance, capacitance, inductance, current/voltage ratings, etc.), that may be applied to influence the operation of a device. Magnetic media, electronic circuits, electrical and optical memory (both volatile and nonvolatile), and firmware are examples of logic. Logic specifically excludes pure signals or software per se (however does not exclude machine memories comprising software and thereby forming configurations of matter). Logic symbols in the drawings should be understood to have their ordinary interpretation in the art in terms of functionality and various structures that may be utilized for their implementation, unless otherwise indicated.

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical, such as an electronic circuit). More specifically, this formulation is used to indicate that this structure is arranged to perform the one or more tasks during operation. A structure can be said to be “configured to” perform some task even if the structure is not currently being operated. A “credit distribution circuit configured to distribute credits to a plurality of processor cores” is intended to cover, for example, an integrated circuit that has circuitry that performs this function during operation, even if the integrated circuit in question is not currently being used (e.g., a power supply is not connected to it). Thus, an entity described or recited as “configured to” perform some task refers to something physical, such as a device, circuit, memory storing program instructions executable to implement the task, etc. This phrase is not used herein to refer to something intangible.

The term “configured to” is not intended to mean “configurable to.” An unprogrammed FPGA, for example, would not be considered to be “configured to” perform some specific function, although it may be “configurable to” perform that function after programming.

Reciting in the appended claims that a structure is “configured to” perform one or more tasks is expressly intended not to invoke 35 U.S.C. § 112(f) for that claim element. Accordingly, claims in this application that do not otherwise include the “means for” [performing a function] construct should not be interpreted under 35 U.S.C § 112(f).

As used herein, the term “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

As used herein, the phrase “in response to” describes one or more factors that trigger an effect. This phrase does not foreclose the possibility that additional factors may affect or otherwise trigger the effect. That is, an effect may be solely in response to those factors, or may be in response to the specified factors as well as other, unspecified factors. Consider the phrase “perform A in response to B.” This phrase specifies that β is a factor that triggers the performance of A. This phrase does not foreclose that performing A may also be in response to some other factor, such as C. This phrase is also intended to cover an embodiment in which A is performed solely in response to B.

As used herein, the terms “first,” “second,” etc. are used as labels for nouns that they precede, and do not imply any type of ordering (e.g., spatial, temporal, logical, etc.), unless stated otherwise. For example, in a register file having eight registers, the terms “first register” and “second register” can be used to refer to any two of the eight registers, and not, for example, just logical registers 0 and 1.

When used in the claims, the term “or” is used as an inclusive or and not as an exclusive or. For example, the phrase “at least one of x, y, or z” means any one of x, y, and z, as well as any combination thereof.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

Although the terms “step” and/or “block” may be used herein to connote different elements of methods employed, the terms should not be interpreted as implying any particular order among or between various steps herein disclosed unless and except when the order of individual steps is explicitly described.

Having thus described illustrative embodiments in detail, it will be apparent that modifications and variations are possible without departing from the scope of the disclosure as claimed. The scope of inventive subject matter is not limited to the depicted embodiments but is rather set forth in the following Claims.

What is claimed is:

1. A lithography mask generation process comprising:
in a forward process:
decomposing a resist pattern into segments; and
rasterizing the segments into a mask pattern using ray casting;
in a backward process:
determining lithography gradients for edge movements that incorporate mask rule constraints; and
propagating the lithography gradients into gradients and velocities for the segments.

2. The lithography mask generation process of claim 1, further comprising:
placing sub-resolution assist features in the mask pattern based on gradients of the mask pattern; and
converting the sub-resolution assist features into additional segments of the resist pattern.

3. The lithography mask generation process of claim 1, further comprising:
configuring a model of a lithography system in which the mask pattern will be deployed as a sum of coherent systems decomposition; and
in the forward process, applying the model to convert the mask pattern into the resist pattern.

4. The lithography mask generation process of claim 3, further comprising:
determining a difference between the resist pattern and a target resist image pattern.

5. The lithography mask generation process of claim 3, further comprising:
determining an edge placement error of the mask pattern by sampling points along edges of shapes within the mask pattern and counting a number of the points for which a distance between the shapes and the resist pattern exceeds a predefined threshold.

6. The lithography mask generation process of claim 5, further comprising:
determining a process variation band for the resist pattern between a maximum manufacturing process condition and a minimum manufacturing process condition.

7. The lithography mask generation process of claim 6, further comprising:
determining a count defining a number of decomposed rectangles that replicate the mask pattern.

8. The lithography mask generation process of claim 7, further comprising:
configuring a process objective that minimizes a weighted sum of the edge placement error, process variation band, and count.

9. The lithography mask generation process of claim 1, further comprising:
iteratively moving the segments based on the gradients and velocities for the segments.

10. A process for generating a lithography mask, the process comprising:
generating resist segments from a collection of Manhattan shapes representing the mask;
generating a mask image from the resist segment set;
applying forward lithography simulation to convert the mask image into a resist image;
performing a loss determination between the resist image and an ideal resist image to generate lithography gradients;
applying the lithography gradients to derive mask gradients; and
interpolating the mask gradients to generate gradients and velocities for the resist segments.

11. The process of claim 10, wherein generating a mask image from the resist segment comprises:
rounding corners of the resist segments;
merging corners of the resist segments; and
rasterization of the resist segments.

12. The process of claim 11, further comprising:
applying a lithography gradient resulting from the rounding and merging of the corners of the resist segments to determine the mask gradients.

13. The process of claim 11, further comprising:
applying the mask gradients to adjust the gradients and velocities of the resist segments.

14. The process of claim 11, wherein rasterization of the resist segments comprises parallelized ray casting.

15. The process of claim 10, wherein generating the resist segments from the collection of Manhattan shapes representing the mask comprises:
segmenting the Manhattan shapes into segments of a pre-defined length; and
assigning a direction vector to each of the segments.

16. The process of claim 15, wherein a direction of a velocity vector vᵢ of each segment sᵢ is restricted to be perpendicular to its direction vector dᵢ.

17. The process of claim 10, wherein the velocities for the resist segments correlate movement of the segments with the lithography gradients.

18. A computer system configured to implement a lithography mask generation process, the computer system comprising:
at least one data process;
a non-volatile machine-readable medium comprising instructions that, when applied to the at least one data processor, configure the computer system to:
in a forward process:
rasterize segments of a resist pattern into a mask pattern using ray casting;
in a backward process:
determine lithography gradients for edge movements that incorporate mask rule constraints; and
propagate the lithography gradients into gradients and velocities for the segments.

19. The computer system of claim 18, the instructions further configuring the computer system to:
place sub-resolution assist features in the mask pattern based on gradients of the mask pattern; and
generate new segments of the resist pattern from the sub-resolution assist features.

20. The computer system of claim 18, the instructions further configuring the computer system to:
configure a model of a lithography system in which the mask pattern will be deployed as a sum of coherent systems decomposition; and
in the forward process, apply the model to convert the mask pattern into the resist pattern.
